(19) United States
(12) Patent Application Publication
(10) Pub. No.: US 2016/0079301 A1
(43) Pub. Date: Mar. 17, 2016

(54) X-RAY DETECTOR

(71) Applicant: GENERAL ELECTRIC COMPANY, Schenectady, NY (US)

(72) Inventors: Jeffery Jon SHAW, Ballston Lake, NY (US); Eric Patrick DAVIS, Wynantskill, NY (US)

(73) Assignee: GENERAL ELECTRIC COMPANY, Schenectady, NY (US)

(21) Appl. No.: 14/487,451

(22) Filed: Sep. 16, 2014

(51) Int. Cl. H01L 27/146; G01T 1/20

(52) U.S. Cl. CPC H01L 27/14663; G01T 1/2018; H01L 27/14692; H01L 27/14685

(57) ABSTRACT

An X-ray detector has a layered structure that includes a substrate, a TFT array disposed on the substrate, a photodiode layer disposed on the TFT array, and a scintillator layer disposed on the photodiode layer. The scintillator layer comprises a particle-in-binder composite that contains a continuous parylene matrix having dispersed therein a plurality of particles that include a scintillator material that emits light in response to the absorption of X-rays.

### BACKGROUND

Digital X-ray imaging systems are used for producing digital data which can be reconstructed into useful radiographic images. In current digital X-ray imaging systems, radiation from a source is directed toward a subject (e.g., a patient in a medical diagnostic application). A portion of the radiation passes through the subject and impacts an X-ray detector. A scintillator layer within the X-ray detector converts the radiation to light photons which are sensed. The X-ray detector includes a matrix of discrete picture elements or pixels, and encodes output signals based upon the quantity or intensity of the radiation impacting each pixel region. Because the radiation intensity is altered as the radiation passes through the subject, the images reconstructed based upon the output signals provide a projection of, e.g., the patient's tissues similar to those available through conventional photographic film techniques.

X-ray detectors and the imaging systems comprising them are particularly useful due to their ability to collect digital data which can be reconstructed into the images required by radiologists and diagnosing physicians, and stored digitally or archived until needed. In conventional film-based radiography techniques, actual films were prepared, exposed, developed and stored for use by the radiologist. While the films provide an excellent diagnostic tool, particularly due to their ability to capture significant anatomical detail, they are inherently difficult to transmit between locations, such as from an imaging facility or department to various physician locations. The digital data produced by direct digital X-ray systems, on the other hand, can be processed and enhanced, stored, transmitted via networks, and used to reconstruct images which can be displayed on monitors and other soft copy displays at any desired location.

Despite their utility in capturing, storing and transmitting image data, digital X-ray systems are still overcoming a number of challenges. For example, the quality of radiographic images generated by X-ray systems is highly dependent upon the scintillator layer's ability to convert radiation into optical photons. Thus, a need exists for improved scintillator layers that allow for the optimal conversion of X-rays to light photons, and for X-ray detectors and systems incorporating the same.

While certain aspects of conventional technologies have been discussed to facilitate disclosure of the invention, Applicant in no way disclaims these technical aspects, and it is contemplated that the claimed invention may encompass one or more of the conventional technical aspects discussed herein.

In this specification, where a document, act or item of knowledge is referred to or discussed, this reference or discussion is not an admission that the document, act or item of knowledge or any combination thereof was, at the priority date, publicly available, known to the public, part of common general knowledge, or otherwise constitutes prior art under the applicable statutory provisions; or is known to be relevant to an attempt to solve any problem with which this specification is concerned.

### BRIEF DESCRIPTION

In one aspect, the present invention relates to an X-ray detector having a layered structure comprising: a substrate; a TFT array disposed on the substrate; a photodiode layer disposed on the TFT array; and a scintillator layer disposed on the photodiode layer. The scintillator layer comprises a particle-in-binder composite comprising a continuous parylene matrix having dispersed therein a plurality of particles comprising a scintillator material that emits light in response to the absorption of X-rays.

In another aspect, the present invention relates to a process for fabricating an X-ray detector, the process comprising: disposing a photodiode layer on a TFT array disposed on a substrate; and disposing a scintillator layer on the photodiode layer. The scintillator layer comprises a particle-in-binder composite comprising a continuous parylene matrix having dispersed therein a plurality of particles comprising a scintillator material that emits light in response to the absorption of X-rays.

In another aspect, the present invention relates to an X-ray imaging system comprising an X-ray detector having a layered structure comprising: a substrate; a TFT array disposed on the substrate; a photodiode layer disposed on the TFT array; and a scintillator layer disposed on the photodiode layer. The scintillator layer comprises a particle-in-binder composite comprising a continuous parylene matrix having dispersed therein a plurality of particles comprising a scintillator material that emits light in response to the absorption of X-rays.

In another aspect, the present invention relates to a scintillator screen comprising a particle-in-binder composite, the composite comprising a continuous parylene matrix having dispersed therein a plurality of particles comprising a scintillator material that emits light in response to the absorption of X-rays.

These and other features, aspects, and advantages of the present invention will become better understood when the following detailed description is read with reference to the accompanying drawings in which like characters represent like parts throughout the drawings.

### DRAWINGS

The present invention will hereinafter be described in conjunction with the following drawing figures, which are not necessarily drawn to scale, and wherein like numerals denote like elements.

FIG. 1 depicts an X-ray imaging system including an X-ray detector and its associated control circuitry for obtaining image data, in accordance with one embodiment of the present disclosure.

FIG. 2 depicts an embodiment of the inventive X-ray detector.

FIG. 3 depicts another embodiment of the inventive X-ray detector.

### DETAILED DESCRIPTION

Aspects of the present invention and certain features, advantages, and details thereof, are explained more fully below with reference to the non-limiting embodiments illustrated in the accompanying drawings. Descriptions of well-known materials, fabrication tools, processing techniques, etc., are omitted so as to not unnecessarily obscure the invention in detail. It should be understood, however, that the detailed description and the specific examples, while indicating embodiments of the invention, are given by way of illustration only, and are not by way of limitation. Various substitutions, modifications, additions and/or arrangements within the spirit and/or scope of the underlying inventive concepts will be apparent to those skilled in the art from this disclosure.

In one aspect, the present invention relates to an X-ray imaging system comprising an X-ray detector having a layered structure comprising: a substrate; a TFT array disposed on the substrate; a photodiode layer disposed on the TFT array; and a scintillator layer disposed on the photodiode layer. The scintillator layer comprises a particle-in-binder composite comprising a continuous parylene matrix having dispersed therein a plurality of particles comprising a scintillator material that emits light in response to the absorption of X-rays.

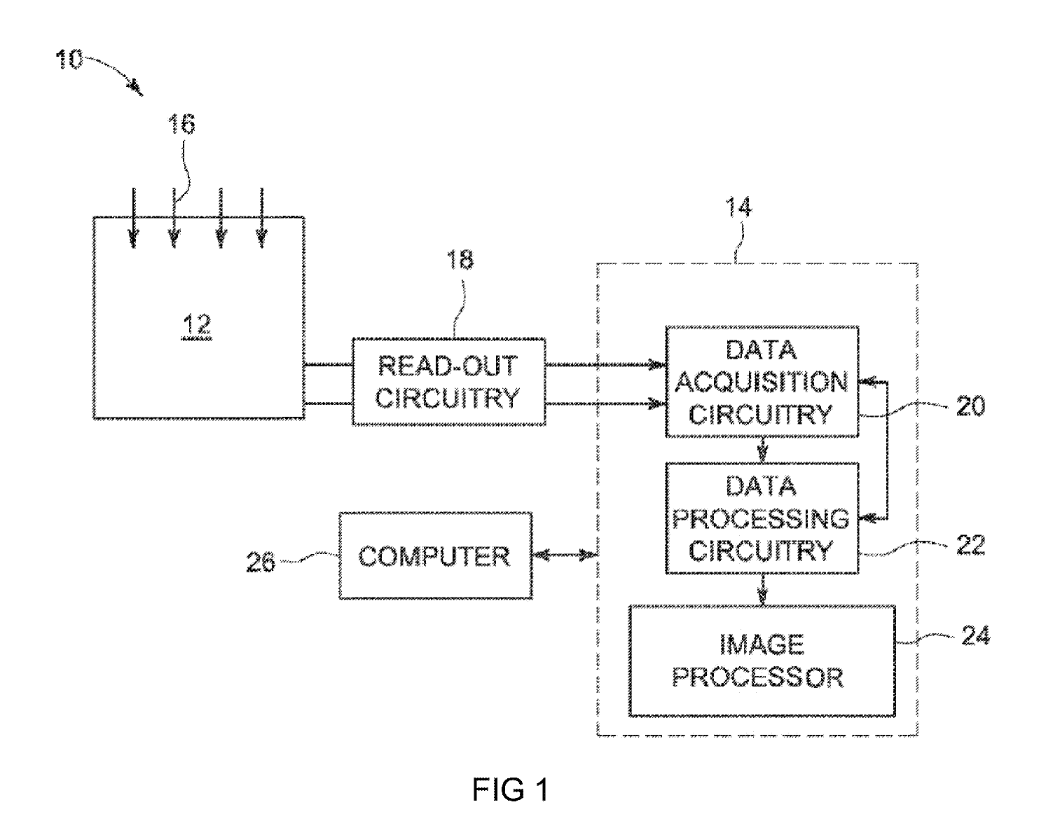

FIG. 1 depicts one embodiment of an X-ray imaging system 10. In the depicted embodiment, the system 10 includes an X-ray detector 12 and control and processing circuitry 14. During imaging, incoming radiation 16 (i.e., X-rays) from an imaging source impinges the X-ray detector 12 after being attenuated by an intervening subject or object undergoing imaging. As will be discussed in greater detail, the X-ray detector 12 includes a scintillator layer (not shown) that absorbs the X-rays 16 and in response emits light of a characteristic wavelength, thereby releasing the absorbed energy. The released energy (i.e., the emitted photons) may be detected by other elements (e.g., a photodiode) of the X-ray detector 12 to generate electrical signals corresponding to the incident radiation 16.

The electrical signals generated by the X-ray detector 12 are in turn acquired by readout circuitry 18 of the control and processing circuitry 14. The signals from the readout circuitry 18 are acquired by the data acquisition circuitry 20. In the depicted embodiment, the acquired signals are supplied to data processing circuitry 22 and/or to image processing circuitry 24. The data processing circuitry 22, when present, may perform various functions such as gain correction, edge detection, sharpening, contrast enhancement, and so forth to condition the data for subsequent processing or image reconstruction. The image processing circuitry or image processor 24 may in turn process the acquired signals to generate an image for a region of interest (ROI) traversed by the radiation 16. In the depicted embodiment, the control and processing circuitry 14 may be controlled by or implemented in a computer 26, which may include or be in communication with an operator workstation and/or an image display workstation. For example, an operator workstation may be utilized by a system operator to provide control instructions to some or all of the components that aid in image generation. The operator workstation may also display the generated image in a remote location, such as on a separate image display workstation.

While in the illustrated embodiment, the control and processing circuitry 14 is depicted external to the X-ray detector 12, in certain embodiments, some or all of these circuitries may be provided as part of the X-ray detector 12. Likewise, in certain embodiments, some or all of the circuitry present in the control and processing circuitry 14 may be provided as part of a computer 26 such as may be embodied in an imaging workstation of operator workstation. Thus, in certain embodiments, aspects of the readout circuitry 18, data acquisition circuitry 20, data processing circuitry 22, image processing circuitry 24, as well as other circuitry of the control and processing circuitry 14, may be provided as part of the X-ray detector 12 and/or as part of a connected computer 26.

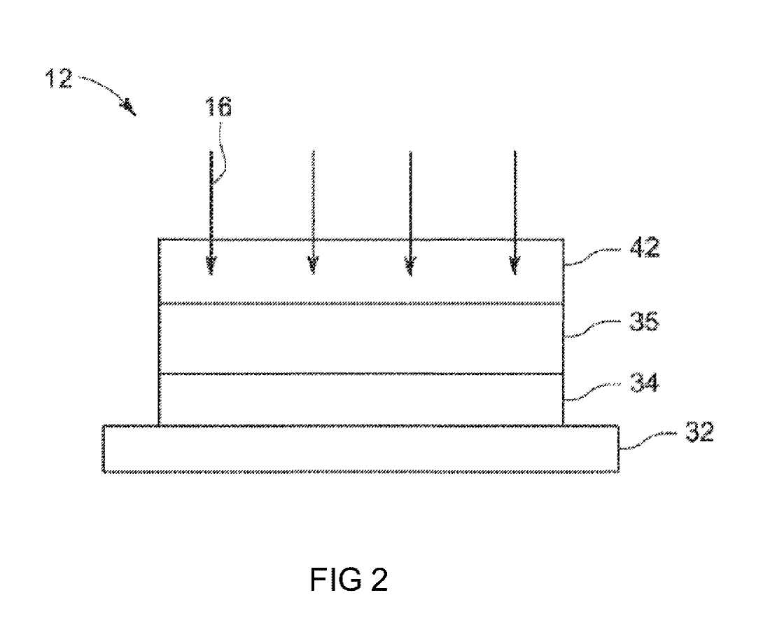

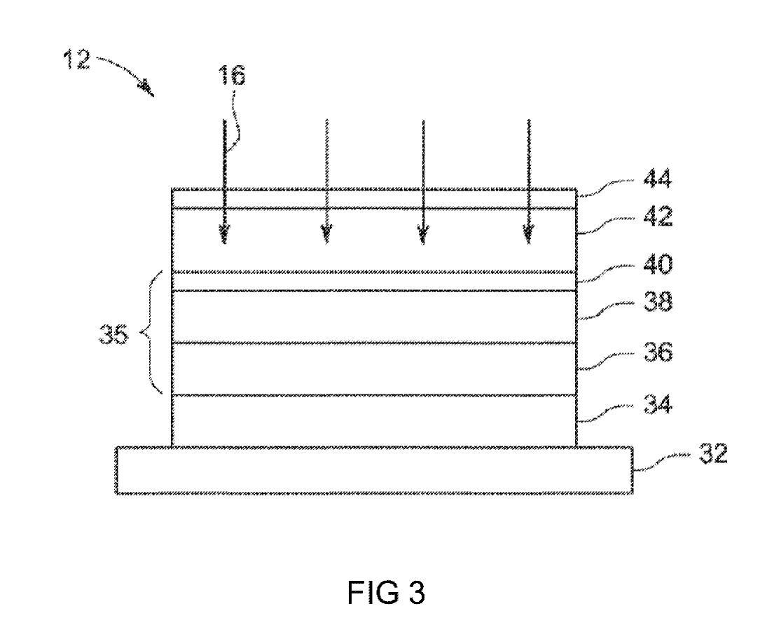

FIG. 2 shows the layered structure of an embodiment of X-ray detector 12 according to the present invention. The X-ray detector 12 includes a pixel element array 34, also referred to as a thin film transistor (TFT) array, disposed over a substrate 32. A photodiode 35, which includes a photodiode layer, is disposed on the TFT array 34. As shown in FIG. 3, the photodiode 35 (which may also be referred to as a photodetector), may include an anode 36, a cathode 40, and a photodiode layer 38 between the anode 36 and cathode 40 which produces charged carriers in response to absorption of light. A scintillator layer 42 is disposed over the photodiode 35. As shown in FIG. 3, in some embodiments, a top cover 44 may cover the scintillator layer 42.

In some embodiments, during an imaging process using the X-ray detector 12 illustrated in FIG. 3, radiation 16 impinges the X-ray detector 12 and passes through the top cover 44 to be absorbed by the scintillator layer 42. The scintillator layer 42 generates optical photons in response to the absorption of radiation 16. The photons generated by the scintillator may pass through the cathode 40 to be absorbed by the photodiode layer 38 of the photodiode 35 which produces charged carriers in response to the absorbed optical wavelength photons. The charge produced by the photodetector 35 is stored by the TFT array 34 and transferred (e.g., via readout circuitry 18 to the control and processing circuitry 14) for further processing and image reconstruction.

The scintillator layer 42 (which, in some embodiments, may also be referred to as a scintillator screen), includes a particle-in-binder composite. The particle-in-binder composite comprises a continuous parylene matrix having dispersed therein a plurality of particles comprising a scintillator material that emits light in response to the absorption of X-rays. Parylene is a generic name for members of a series of poly(p-xylylene) polymers. A description of different parylenes and fundamental aspects relating thereto is described, for example, in U.S. Pat. No. 8,732,922. Included in the different types of parylenes are parylene N, parylene C, parylene D, parylene AF-4, parylene VT-4, parylene A, parylene AM, and parylene X. In some embodiments of the invention, the scintillator layer 42 comprises one or more of parylene C, parylene N, and parylene D. In particular embodiments, the scintillator layer 42 comprises parylene C.

The plurality of particles dispersed within the parylene matrix of scintillator layer 42 comprise a scintillator material that emits light in response to the absorption of X-rays. The scintillator materials used in the scintillator layer 42 are indirect conversion scintillator materials. Persons having ordinary skill in the art will readily be able to select appropriate indirect conversion scintillator material(s). In some embodiments, the scintillator material comprises one or more of cesium iodide doped with thallium, lutetium oxide doped with europium, gadolinium oxysulfide doped with at least one of terbium and europium, gadolinium tantalate doped with europium, cadmium tungstate (CdWO₄), bismuth germanate (BGO), yttrium aluminum garnet doped with cerium, and sodium iodide doped with thallium.

In some embodiments, the plurality of particles dispersed within the parylene matrix have an average particle size of 0.5 μm to 50 μm, for example, 0.5, 0.6, 0.7, 0.8, 0.9, 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, or 50 μm, including any and all ranges and subranges therein (e.g., 0.5 to 40 μm, 1.5 to 50 μm, etc.). In some embodiments, the particles have an average particle size of 2.5 μm to 25 μm. In some embodiments, the particles constituting the plurality of particles are chosen from distributions of different mean particle sizes in order to increase the particle packing fraction in scintillator layer 42.

In some embodiments, the X-ray detector 16 of FIG. 3 may be fabricated through a process comprising: disposing photodiode layer 38 on TFT array 34, and disposing scintillator layer 42 on the photodiode layer 38. Throughout this disclosure, where a component (e.g., a layer) is “disposed” on another component, said disposal includes both direct and indirect disposal. For example, in FIG. 3, photodiode layer 38 is considered to be disposed on TFT array 34, even though the disposal is indirect (since photodiode layer 38 is in fact, in the depicted embodiment, disposed directly on anode 36).

Scintillator layer 42 may be formed by depositing a layer of the plurality of particles, and subsequently vapor depositing the parylene onto the plurality of particles. The parylene functions as the binder in the particle-in-binder (PIB) composite, and it replaces traditional binders such as silicones and epoxies. While traditional PIB's are typically prepared by mixing the binder with scintillator particles, then depositing the mixture, scintillator layer 42 may be formed by first depositing the scintillator particles, then applying a parylene binder matrix, e.g., via vapor deposition. In such embodiments, the vapor penetrates into even small gaps between the particles, binding the screen together in an optimal manner.

The inventive embodiments are advantageous in that the parylene binder can offer high optical transparency, which is a goal for many scintillators. Alternatively, it is also possible to deposit the parylene in such a way that it is slightly opaque, which may be useful in an application for which a very high resolution screen is desired and in which the X-ray flux is relatively high. Parylene has a higher index of refraction as compared with other conventional binder materials, which results in higher white output from the scintillator screen, which is another advantage associated with the present invention.

In some embodiments, during formation of scintillator layer 42, a gasket is placed around a perimeter of an active area of an X-ray panel in order to contain the plurality of particles. For example, a perimeter gasket may be attached to an active portion of the X-ray panel, and scintillator particles may be dispensed into the space enclosed by the gasket, and optionally manipulated (e.g., by mechanical agitation or compression) to increase particle packing density. In other embodiments, the gasket is formed by printing a bead of, e.g., epoxy, around the perimeter of the X-ray panel. In alternative embodiments, a screen may be formed independent of an X-ray panel (i.e., freestanding). In such embodiments, a perimeter gasket may be attached to a reflective sheet, and scintillator particles may be dispensed into the space enclosed by the gasket, and optionally manipulated (e.g., by mechanical agitation or compression) to increase particle packing density. In another freestanding embodiment, the particle-in-binder screen may be formed using the above-described epoxy bead method, where the epoxy is applied to any desirable substrate, such as a reflective sheet. This may be accomplished, in some embodiments (for both freestanding and other screens), by a robotic dispense system. The thickness of a scintillator layer may be controlled, e.g., either by controlling the weight of the scintillator particles and using a consistent dispense process or by filling the gasket and using it to define the height. Once a particle layer of suitable height and area has been prepared, it may be placed inside a commercial parylene coater.

Because inventive embodiments do not require pre-mixing of the particles and binder (i.e., parylene), the particles may be prepared with the maximum possible packing density. In some embodiments, scintillator layer 42 comprises about 50 to 95 wt % of the plurality of particles, e.g., 50, 51, 52, 53, 54, 55, 56, 57, 58, 59, 60, 61, 62, 63, 64, 65, 66, 67, 68, 69, 70, 71, 72, 73, 74, 75, 76, 77, 78, 79, 80, 81, 82, 83, 84, 85, 86, 87, 88, 89, 90, 91, 92, 93, 94, or 95 wt %, including any and all ranges and subranges therein (e.g., 65 to 90 wt %, etc.). In some embodiments, scintillator layer 42 comprises about 5 to 50 wt % of the parylene, e.g., 5, 6, 7, 8, 9, 10, 11, 12, 13, 14, 15, 16, 17, 18, 19, 20, 21, 22, 23, 24, 252, 26, 27, 28, 29, 30, 31, 32, 33, 34, 35, 36, 37, 38, 39, 40, 41, 42, 43, 44, 45, 46, 47, 48, 49, or 50 wt %, including any and all ranges and subranges therein (e.g., 10 to 35 wt %, etc.). By allowing for high particle loading as compared to traditional techniques, the present invention can achieve high X-ray absorption in thinner, and thus higher-resolution, screens that would otherwise be achieved. Embodiments of the scintillator layer 42 also offer a high degree of flexibility, and thus possess a high resistance to damage from shock or drop, which makes them attractive for rugged detectors.

In some embodiments, the formation of scintillator layer 42 comprises one or more mechanical vibration or mechanical compression steps, which serve to increase the packing density of the particles.

In some embodiments, scintillator layer 42 consists essentially of the particle-in-binder composite comprising the continuous parylene matrix having dispersed therein the plurality of particles comprising the scintillator material that emits light in response to the absorption of X-rays.

In some embodiments, the scintillator layer 42 is 0.025 to 4 mm thick (e.g., 0.025, 0.03, 0.04, 0.05, 0.06, 0.07, 0.08, 0.09, 1.0, 1.1, 1.2, 1.3, 1.4, 1.5, 1.6, 1.7, 1.8, 1.9, 2.0, 2.1, 2.2, 2.3, 2.4, 2.5, 2.6, 2.7, 2.8, 2.9, 3.0, 3.1, 3.2, 3.3, 3.4, 3.5, 3.6, 3.7, 3.8, 3.9, or 4.0 mm thick), including any and all ranges and subranges therein (for example, 0.05 to 4 mm thick, 0.05 to 1 mm thick, etc.)

Photodiode layer 38 produces charged carriers in response to the absorption of the optical photons generated by scintillator layer 42. Photodiode layers are well known in the art, and persons having ordinary skill in the art can readily select photodiode layers for use in the inventive X-ray detectors. In some embodiments, the invention provides organic X-ray detectors that include an organic photodiode layer. Examples of suitable organic photodiode layers are disclosed, for example, in commonly-owned U.S. application Ser. No. 13/955,55. Additional photodiode layers are also disclosed in, e.g., commonly-owned U.S. Pat. No. 8,581,254. In some embodiments, the photodiode layer may be patterned.

Substrate 32 may be composed of a rigid or flexible material. Examples of suitable materials for the substrate include glass, which may be rigid or flexible, plastics such as polyethylene terephthalate, polybutylene phthalate, polyethylene naphthalate, polystyrene, polycarbonate, polyether sulfone, polyallylate, polyimide, polycycloolefin, norbornene resins, and fluoropolymers, metals such as stainless steel, aluminum, silver and gold, metal oxides, such as titanium oxide and zinc oxide, and semiconductors such as silicon. Combinations of materials may also be used. By using an unbreakable material instead of a fragile glass substrate for the X-ray detector, the components and materials designed to absorb bending stress or drop shock can be reduced in size and weight or eliminated, and the overall weight and thickness of the detector can be reduced. Removing costly materials which are used to protect the glass substrate decreases the overall cost of the detector.

Thin film transistor (TFT) layer 34 is a two dimensional array of passive or active pixels which store charge for read out by electronics, disposed on an active layer formed of amorphous silicon or an amorphous metal oxide, or organic semiconductors. Suitable amorphous metal oxides include zinc oxide, zinc tin oxide, indium oxides, indium zinc oxides (In—Zn—O series), indium gallium oxides, gallium zinc oxides, indium silicon zinc oxides, and indium gallium zinc oxides (IGZO). IGZO materials include InGaO₃(ZnO)ₘ where m is <6) and InGaZnO₄. Suitable organic semiconductors include, but are not limited to, conjugated aromatic materials, such as rubrene, tetracene, pentacene, perylenediimides, tetracyanoquinodimethane and polymeric materials such as polythiophenes, polybenzodithiophenes, polyfluorene, polydiacetylene, poly(2,5-thiophenylene vinylene) and poly(p-phenylene vinylene) and derivatives thereof.

In some embodiments, X-ray detector 12 may include at least one charge blocking layer. The charge blocking layer may be a continuous patterned or unpatterned conductive layer. In some embodiments, the charge blocking layer may comprise one or more of poly-TPD (poly(4-butylphenyl-diphenyl-amine), poly(N,N′-bis(4-butylphenyl)-N,N′-bis(phenyl)benzidine, 4,4′,N,N′-diphenylcarbazole, 1,3,5-tris(3-methyldiphenyl-amino)benzene, N,N′-bis(1-naphtalenyl)—N—N′-bis(phenylbenzidine), N,N′-Bis-(3-methylphenyl)-N,N′-bis(phenyl)benzidine, N,N′-bis(2-naphtalenyl)-N—N′-bis-(phenylbenzidine), 4,4′,4″-tris(N,N-phenyl-3-methylphenylamino)triphenylamine, poly[9,9-dioctylfluorenyl-2,7-dyil)-co-(N,N′bis-(4-butylphenyl-1,1′-biphenylene-4,4-diamine)], poly(N,N′-bis(4-butylphenyl)-N,N′-bis(phenyl)benzidine, poly[(9,9-dihexylfluorenyl-2,7-diyl)-co-(N,N′bis{p-butylphenyl}-1,4-diamino-phenylene)], NiO, MoO3, tri-p-tolylamine, 4,4′,4″-tris[phenyl(m-tolyl)amino]triphenylamine, 4,4′,4″-tris[2-naphthyl(phenyl)amino]triphenylamine, 1,3,5-tris[(3-methylphenyl)phenylamino]benzene, 1,3,5-tris(2-(9-ethylcabazyl-3)ethylene)benzene, 1,3,5-tris(diphenylamino)benzene, tris[4-(diethylamino)phenyl]amine, tris(4-carbazoyl-9-ylphenyl)amine, titanyl phthalocyanine, tin(IV) 2,3-naphthalocyanine dichloride, N,N,N′,N′-tetraphenyl-naphthalene-2,6-diamine, tetra-N-phenylbenzidine, N,N,N′,N′-tetrakis(2-naphthyl) benzidine, N,N,N′,N′-tetrakis(3-methylphenyl)-3,3′-dimethylbenzidine, N,N,N′,N′-tetrakis(4-methoxyphenyl)benzidine, poly(2-vinylnaphthalene), poly(2-vinylcarbazole), poly(N-ethyl-2-vinylcarbazole), poly(copper phthalocyanine), poly[bis(4-phenyl)(2,4,6-trimethylphenyl)amine], dipyrazino[2,3-f:2′,3′-h]quinoxaline-2,3,6,7,10,11-hexacarbonitrile 99%, N,N′-diphenyl-N,N′-di-p-tolylbenzene-1,4-diamine, 4-(diphenylamino)benzaldehyde diphenylhydrazone, N,N′-di(2-naphthyl-N,N′-diphenyl)-1,1′-biphenyl-4,4′-diamine, 9,9-dimethyl-N,N′-di(1-naphthyl)-N,N′-diphenyl-9H-fluorene-2,7-diamine, 2,2′-dimethyl-N,N′-di-[(1-naphthyl)-N,N′-diphenyl]-1,1′-biphenyl-4,4′-diamine, 4-(dibenzylamino)benzaldehyde-N,N-diphenyl-hydrazone, 4,4′-Cyclohexylidenebis[N,N-bis(4-methylphenyl)benzenamine], N,N′-Bis(phenanthren-9-yl)-N,N′-bis(phenyl)-benzidine, N,N′-Bis(3-methylphenyl)-N,N′-diphenylbenzidine, 4,4′-Bis(3-ethyl-N-carbazolyl)-1,1′-biphenyl, 1,4-Bis(diphenylamino)benzene, 4,4′-Bis(N-carbazolyl)-1,1′-biphenyl, 4,4′-Bis(N-carbazolyl)-1,1′-biphenyl, and 1,3-Bis(N-carbazolyl)benzene.

### Examples

Certain non-limiting embodiments of the invention are described in the following examples.

Example #1. A scintillator screen was formed using parylene as the binder. The screen was fabricated by placing a layer of gadolinium oxysulfide doped with terbium scintillating particles in a 3 inch by 3 inch, 1 mm deep square substrate well inside a commercial parylene coater. Vapor depositing a 7.5 μm thick layer of parylene on the part resulted in the parylene penetrating throughout the particle layer, thereby forming a continuous matrix and binding the particles together to form a 1-mm thick PIB screen.

Example #2. A scintillator screen was formed using Parylene as a binder. The screen was fabricated by placing a layer of scintillating particles composed of gadolinium oxysulfide doped with terbium inside a square recess of dimensions 7.5 cm×7.5 cm and 0.1 cm depth cut into a block of Teflon. The sample was placed into a commercial Parylene coater and 7.5 microns of Parylene-C was deposited, as measured on a witness slide placed inside the chamber adjacent to the sample. The Parylene coating bound the particles together, forming a continuous matrix. The resulting screen was brighter than a comparable screen using a conventional binder with index of refraction 1.4. In another example, a reflective sheet was laminated onto a glass substrate. A perimeter gasket of epoxy was formed on the reflective layer by means of a robotic dispense system. The epoxy was planarized to yield a gasket with a well-defined height of 0.25 mm. The gasket enclosed an area with dimensions 6 cm×6 cm. The sample was coated with Parylene-C in a commercial deposition system. In this configuration, the reflective layer may optionally be pulled back and cut to size to provide a scintillator screen with integrated reflector.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include” (and any form of include, such as “includes” and “including”), “contain” (and any form contain, such as “contains” and “containing”), and any other grammatical variant thereof, are open-ended linking verbs. As a result, a method or device that “comprises”, “has”, “includes” or “contains” one or more steps or elements possesses those one or more steps or elements, but is not limited to possessing only those one or more steps or elements. Likewise, a step of a method or an element of a device that “comprises”, “has”, “includes” or “contains” one or more features possesses those one or more features, but is not limited to possessing only those one or more features.

As used herein, the terms “comprising,” “has,” “including,” “containing,” and other grammatical variants thereof encompass the terms “consisting of” and “consisting essentially of.”

The phrase “consisting essentially of” or grammatical variants thereof when used herein are to be taken as specifying the stated features, integers, steps or components but do not preclude the addition of one or more additional features, integers, steps, components or groups thereof but only if the additional features, integers, steps, components or groups thereof do not materially alter the basic and novel characteristics of the claimed composition, device or method.

All publications cited in this specification are herein incorporated by reference as if each individual publication were specifically and individually indicated to be incorporated by reference herein as though fully set forth.

Subject matter incorporated by reference is not considered to be an alternative to any claim limitations, unless otherwise explicitly indicated.

Where one or more ranges are referred to throughout this specification, each range is intended to be a shorthand format for presenting information, where the range is understood to encompass each discrete point within the range as if the same were fully set forth herein.

While several aspects and embodiments of the present invention have been described and depicted herein, alternative aspects and embodiments may be affected by those skilled in the art to accomplish the same objectives. Accordingly, this disclosure and the appended claims are intended to cover all such further and alternative aspects and embodiments as fall within the true spirit and scope of the invention.

1. An X-ray detector having a layered structure comprising:
a substrate;
a TFT array disposed on the substrate;
a photodiode layer disposed on the TFT array; and
a scintillator layer disposed on the photodiode layer;
wherein the scintillator layer comprises a particle-in-binder composite comprising a continuous parylene matrix having dispersed therein a plurality of particles having an average particle size ranging from 0.5 μm to 50 μm and comprising gadolinium oxysulfide doped with at least one of terbium and europium.

2. An X-ray detector according to claim 1, wherein the TFT array has an active layer formed from amorphous silicon.

3. An X-ray detector according to claim 1, wherein the TFT array has an active layer formed from IGZO.

4. An X-ray detector according to claim 1, wherein the parylene comprises one or more of parylene C, parylene N, and parylene D.

5. An X-ray detector according to claim 4, wherein the parylene comprises parylene C.

6. (canceled)

7. (canceled)

8. An X-ray detector according to claim 1, wherein the particles have an average particle size of 2.5 μm to 25 μm.

9. An X-ray detector according to claim 1, wherein the X-ray detector is an organic X-ray detector comprising an organic photodiode layer.

10. An X-ray detector according to claim 1, wherein the scintillator layer comprises:
50 to 95 wt % of the plurality of particles; and
5 to 50 wt % of the parylene.

11. An X-ray detector according to claim 10, wherein the scintillator layer comprises:
65 to 90 wt % of the plurality of particles; and
10 to 35 wt % of the parylene.

12. A process for fabricating an X-ray detector, the process comprising
disposing a photodiode layer on a TFT array disposed on a substrate; and
disposing a scintillator layer on the photodiode layer;
wherein the scintillator layer comprises a particle-in-binder composite comprising a continuous parylene matrix having dispersed therein a plurality of particles having an average particle size ranging from 0.5 μm to 50 μm and comprising gadolinium oxysulfide doped with at least one of terbium and europium, cesium iodide doped with thallium, or lutetium oxide doped with europium.

13. A process according to claim 12, wherein the scintillator layer is formed by depositing a layer of the plurality of particles, and subsequently vapor depositing the parylene onto the plurality of particles.

14. (canceled)

15. A process according to claim 12, wherein the scintillator layer comprises:
65 to 95 wt % of the plurality of particles; and
5 to 35 wt % of the parylene.

16. An X-ray imaging system comprising an X-ray detector having a layered structure comprising:
a substrate;
a TFT array disposed on the substrate;
a photodiode layer disposed on the TFT array; and
a scintillator layer disposed on the photodiode layer;
wherein the scintillator layer comprises a particle-in-binder composite comprising a continuous parylene matrix having dispersed therein a plurality of particles having an average particle size ranging from 0.5 μm to 50 μm and comprising gadolinium oxysulfide doped with at least one of terbium and europium, cesium iodide doped with thallium, or lutetium oxide doped with europium.

17. An X-ray imaging system according to claim 16, wherein the TFT array has an active layer formed from amorphous silicon or IGZO.

18. An X-ray imaging system according to claim 16, wherein the parylene comprises one or more of parylene C, parylene N, and parylene D.

19. (canceled)

20. An X-ray imaging system according to claim 16, wherein the scintillator layer comprises:
65 to 95 wt % of the plurality of particles; and
5 to 35 wt % of the parylene.

21. A scintillator screen comprising a particle-in-binder composite, the composite comprising a continuous parylene matrix having dispersed therein a plurality of particles having an average particle size ranging from 0.5 μm to 50 μm and comprising gadolinium oxysulfide doped with at least one of terbium and europium, cesium iodide doped with thallium, or lutetium oxide doped with europium.

22. The scintillator screen according to claim 21, wherein the parylene comprises one or more of parylene C, parylene N, and parylene D.

23. (canceled)

24. The scintillator screen according to claim 21, wherein the scintillator layer comprises:
65 to 95 wt % of the plurality of particles; and
5 to 35 wt % of the parylene.
